(19) United States
(12) Patent Application Publication
(10) Pub. No.: US 2005/0152118 A1
(43) Pub. Date: Jul. 14, 2005

(54) Device to cool integrated circuit element and disk drive having the same

(75) Inventor: Sung-wook Cho, Seoul (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 10/926,070

(22) Filed: Aug. 26, 2004

(30) Foreign Application Priority Data
Jan. 8, 2004 (KR) 2004-1106

(51) Int. Cl. H05K 7/20

(52) U.S. Cl. 361/707

(57) ABSTRACT

A device to cool an integrated circuit element, the device having a printed circuit board with a through hole smaller than the integrated circuit element; a cooling pad attached to a first element surface of the integrated circuit element, and positioned inside the through hole; and a heat transfer portion connected with a heat absorption body and making contact with the cooling pad, to transfer heat to the heat absorption body, so that the integrated circuit element is cooled by transferring the heat generated in the integrated circuit element, which is mounted on a first surface of the printed circuit board, to the heat absorption body, which is disposed facing a second surface of the printed circuit board opposite the first surface.

### CROSS-REFERENCE TO RELATED APPLICATIONS

This application claims the priority of Korean Patent Application No. 2004-1106, filed on Jan. 8, 2004, in the Korean Intellectual Property Office, the disclosure of which is incorporated herein in its entirety by reference.

### BACKGROUND OF THE INVENTION

1. Field of the Invention

The present invention relates to a device to cool an integrated circuit element and a disk drive having the same, and more particularly, to a device to cool an integrated circuit element and a disk drive having the same, in which the device is capable of transferring heat through a first surface of the integrated circuit mounted on a printed circuit board.

2. Description of the Related Art

FIG. 1 is a cross sectional view showing a conventional device for cooling an integrated circuit element. Referring to FIG. 1, components are mounted on first and second surfaces 11 and 12 of a printed circuit board 1. A heat absorption body 4 is placed opposite to the second surface 12 of the printed circuit board 1. Reference number 2 designates an integrated circuit element, which generates so much heat as to necessitate cooling in an operating condition. The integrated circuit element 2 is mounted on the second surface 12 facing the heat absorption body 4. A cooling pad 3 is attached to the integrated circuit element 2. The cooling pad 3 makes contact with the heat absorption body 4. According to such construction, the conventional device for cooling the integrated circuit element transfers the heat generated in the integrated circuit element 2 across the cooling pad 3, to the heat absorption body 4, to cool the integrated circuit element 2.

But the above-described conventional device for cooling the integrated circuit element has the following problems. Since the heat absorption body 4 is placed facing the second surface 12 of the printed circuit board 1, components needing to be cooled must be mounted on the second surface 12. In other words, since each component must be classified according to necessity of cooling and then mounted on the first or second surface 11 or 12 based on the classification, a component mounting process must be redundantly accomplished. Due to the same reason, circuit pattern design of a printed circuit board 1 is also limited.

In the case of a single surface mount type printed circuit board, the second surface 12 facing the heat absorption body 4 is typically used as a mounting surface. But as is shown in FIG. 2, when the first surface 11 must be used as a mounting surface, the heat generated in the integrated circuit element 2 can not be effectively transferred to the heat absorption body 4 because the printed circuit board 1 obstructs heat transfer between the integrated circuit element 2 and the heat absorption body 4.

### SUMMARY OF THE INVENTION

The present invention provides an improved device to cool an integrated circuit element, the device transferring heat generated in the integrated circuit element to a heat absorption body even when the heat absorption body is located on a side of a printed circuit board opposite to a surface of the printed circuit board on which the integrated circuit element is mounted. In addition, the present invention provides a disk drive having the device to cool the integrated circuit element described above.

According to an aspect of the present invention, there is provided a device to cool an integrated circuit element by transferring heat generated in the integrated circuit element to a heat absorption body, the device comprising: a printed circuit board having a through hole, the through hole being smaller than the integrated circuit element; a cooling pad attached to a first element surface of the integrated circuit element, the cooling pad being located inside the through hole; and a heat transfer portion connected with the heat absorption body and making contact with the cooling pad through the through hole to transfer the heat to the heat absorption body, the integrated circuit element being mounted on a first surface of the printed circuit board and the heat absorption body being disposed facing a second surface of the printed circuit board opposite the first surface.

According to another aspect of the present invention, there is provided a disk drive comprising: a driver unit, which comprises a spindle motor rotating a disk, and an optical pick-up unit accessing the disk to record and/or reproduce data; a control unit, which comprises a printed circuit board having first and second surfaces, a through hole, and at least one integrated circuit element that is mounted on the first surface of the printed circuit board, the through hole being smaller than the integrated circuit element; a heat absorption body, which is disposed facing the second surface of the printed circuit board; and a device to cool the integrated circuit element, which connects the integrated circuit element with the heat absorption body to cool heat generated in the integrated circuit element, wherein the device for cooling the integrated circuit element comprises a cooling pad attached to a first element surface of the integrated circuit element, the cooling pad being located inside the through hole; and a heat transfer portion connected with the heat absorption body, and making contact with the cooling pad through the through hole to transfer the heat to the heat absorption body.

According to one aspect, the heat transfer portion is formed as a single body integrated with the heat absorption body.

According to one aspect, the printed circuit board is a single surface mounting type, in which components are mounted only on the first surface.

According to one aspect, the disk drive further comprises: an upper case; a lower case; and a tray slidably coupled with the lower case and on which the driving unit is mounted, wherein the printed circuit board is coupled with the lower case, the first and second surfaces of the printed circuit board face to the upper and lower cases, respectively, and the heat absorption body is the lower case. According to one aspect, the heat transfer portion is formed as a single body integrated with the lower case. According to one aspect, the lower case is made by press-working a metal sheet.

Additional aspects and/or advantages of the invention will be set forth in part in the description which follows, and in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings, of which:

FIG. 1 is a cross sectional view showing a conventional device for cooling an integrated circuit element;

FIG. 2 is a cross sectional view showing another conventional device for cooling an integrated circuit element;

FIG. 3 is a perspective view showing a device to cool an integrated circuit element according to an embodiment of the present invention;

FIG. 4 is a cross sectional view taken along line I-I′ of FIG. 3;

FIG. 5 is a perspective view showing of a disk drive according to an embodiment of the present invention;

FIG. 6 is a cross sectional view taken along line II-II′ of FIG. 5;

FIG. 7 is a cross sectional view taken along line III-III′ of FIG. 5; and

FIG. 8 is a cross sectional view showing an embodiment of the present invention in which a dual mounting surface type printed circuit board is used.

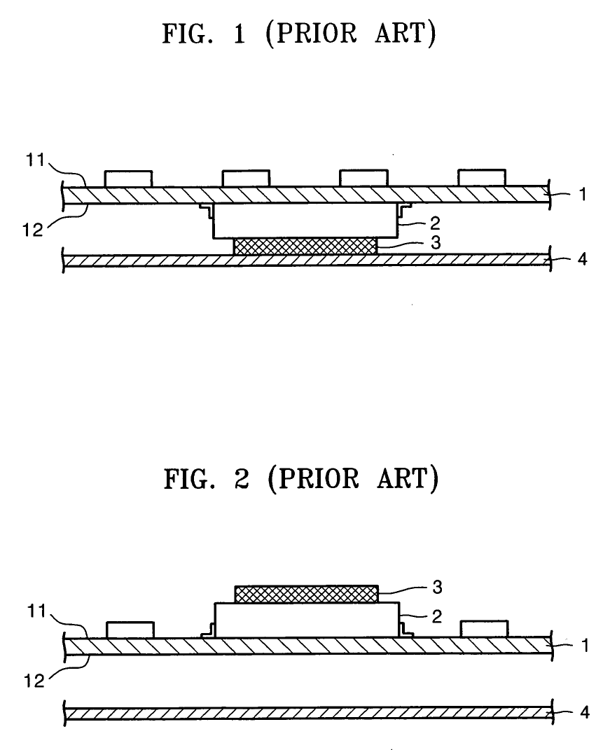

### DETAILED DESCRIPTION

Reference will now be made in detail to the embodiments of the present invention, examples of which are illustrated in the accompanying drawings, wherein like reference numerals refer to the like elements throughout. The embodiments are described below to explain the present invention by referring to the figures.

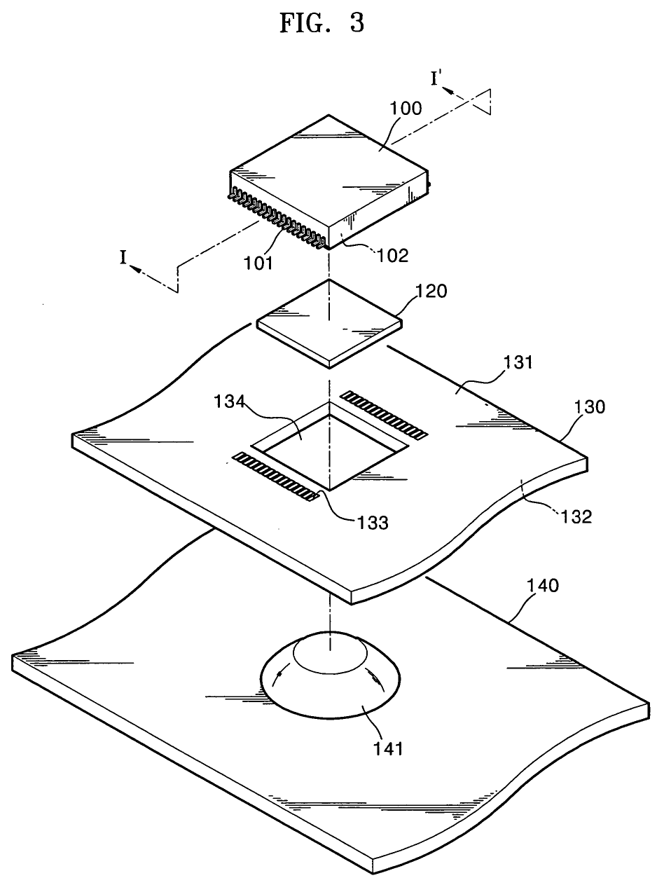

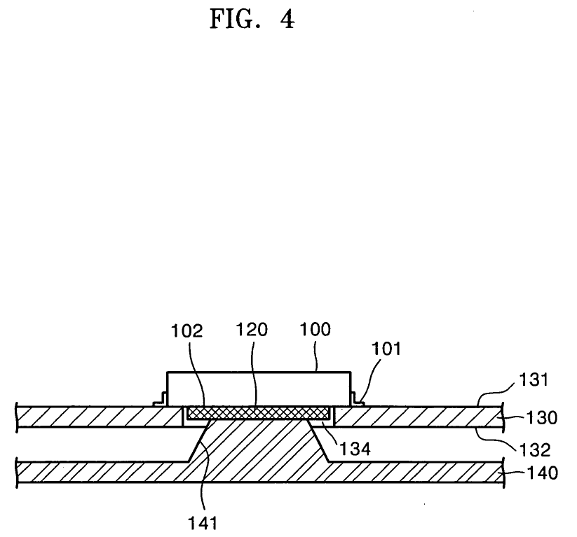

Referring to FIGS. 3 and 4, a printed circuit board 130 has first and second surfaces 131 and 132. An integrated circuit element 100 is mounted on the first surface 131 of the printed circuit board 130. For this purpose, a mounting portion 133 is prepared on the first surface 131 of the printed circuit board 130 to mount a lead frame 101 of the integrated circuit element 100. In addition, a through hole 134 is prepared on the printed circuit board, so that a first element surface 102 of the integrated circuit element 100 is exposed through the through hole 134 when the integrated circuit element 100 is mounted on the printed circuit board 130. A cooling pad 120 is attached to the first element surface 102 of the integrated circuit element 100. Though FIGS. 3 and 4 do not illustrate its figure in detail, the cooling pad 120 plays a part in expanding a cooling area to effectively radiate the heat generated in the integrated circuit element 100. According to one embodiment, the cooling pad 120 is attached to the first element surface 102 of the integrated circuit element 100, and then the integrated circuit element 100 is mounted on the printed circuit board 130 to place the cooling pad 120 inside of the through hole 134.

According to another embodiment, the integrated circuit element 100 is mounted on the printed circuit board 100, and then the cooling pad 120 is attached to the first element surface 102 of the integrated circuit element 100 through the through hole 134. In addition, according to one embodiment, the cooling pad 120 is integrated with the integrated circuit element 100 in a single body. Reference number 140 designates a heat absorption body. According to one embodiment, the heat absorption body 140 is made of, for example, a metallic material having a high thermal conductivity. The heat absorption body 140 is disposed facing the second surface 132 of the printed circuit board 130, and makes contact with the cooling pad 120 through the through hole 134. The heat generated in the integrated circuit element 100 is transferred to the heat absorption body 140 through the cooling pad 120. Accordingly, the integrated circuit element 100 can be cooled. According to one embodiment, a portion (i.e., a heat transfer portion 141) to make substantial contact with the cooling pad 120, to transfer the heat from the cooling pad 120 to the heat absorption body 140 is integrated with the heat absorption body 140 in a single body. According to another embodiment, the heat transfer portion 141 is separately manufactured and then attached to or combined with the heat absorption body 140.

According to the above-described embodiments, even when the integrated circuit element 100 needing to be cooled is mounted on the first surface 131 of the printed circuit board 130 and the heat absorption body 140 is disposed facing to the second surface 132 of the printed circuit board 130, the heat generated in the integrated circuit element 100 is transferred to the heat absorption body 140. Therefore, since it is possible to remove the limitation that the integrated circuit element 100 needing to be cooled must be mounted on the second surface 132 of the printed circuit board 130 facing the heat absorption body 140, freedom in designing the printed circuit board 130 is achieved.

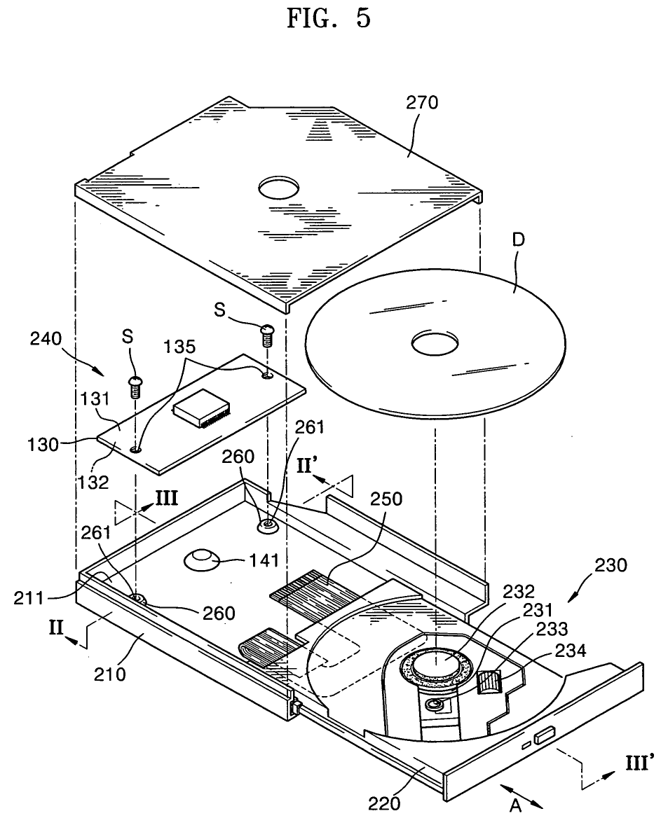

FIGS. 5 through 7 show another embodiment of the present invention. A disk drive, which will be described below, is a slim type disk drive that is typically installed in a portable computer, such as a notebook computer.

Referring to FIG. 5, a tray 220 is installed in a lower case 210 to slide in the direction of “A”. The lower case 210 and the tray 220 are slightly separated from each other in an up/down direction, as is shown in FIG. 7. In the tray 220, a driving unit 230, including a spindle motor 231 and an optical pick-up 233, is installed. The spindle motor 231 rotates an optical disk D, and has a turntable 232 with a rotating axis. The optical disk D is mounted on the turntable 232. The optical pick-up 233 slides in a radial direction of the optical disk D to access a recording surface of the optical disk D to record and/or reproduce data. Reference number 234 designates a driving motor, which makes the optical pick-up 233 slide in the radial direction of the optical disk D.

A control unit 240 is installed in the lower case 210. The control unit 240 controls the operation of the optical disk drive. The control unit 240 is electrically connected with electrical components installed in the tray 220, such as the optical pick-up 233, the spindle motor 231, and the driving motor 234, through, for example, a flexible printed circuit (FPC) 250. Reference number 270 designates an upper case.

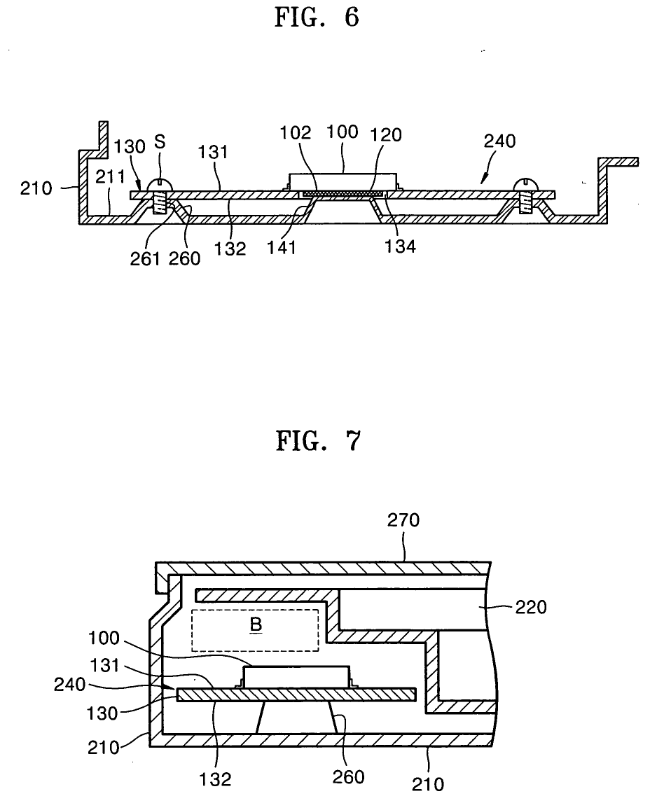

The control unit 240 includes the printed circuit board 130 having the first and second surfaces 131 and 132 and one or more integrated circuit elements 100 mounted on the printed circuit board 130. Referring to FIGS. 5 and 6, the lower case 210 comprises a fixing member 260 for the control unit 240. The fixing member 260 protrudes toward an upper direction from the upper surface 211 of the lower case 210, and has a first fixing hole 261 to fasten a screw S. The printed circuit board 130 has a second fixing hole 135 that aligns with the first fixing hole 261. The control unit 240 is combined with the lower case 210 by placing the printed circuit board 130 on the fixing member 260 and then fastening the screw S through the first and second fixing holes 135 and 261. According to another embodiment, the control unit 240 is fixed with the lower case 210 using one of various other methods.

As is shown in FIG. 7, the tray 220 comes to slide almost up to an end of the control unit 240 when the tray 220 is completely loaded. Therefore, in this embodiment, since it is physically impossible to combine the control unit 240 with the upper case 270, the control unit 240 is combined with the lower case 210 as described above. Currently, as a number of components used in the control unit 240 is decreasing due to progress in integrated circuit technology, there has been an attempt to mount the components on a single surface of the printed circuit 130. This reduces a cost for mounting components. In such a case, it is necessary to review which surface is more effective to mount the components on, between the first and second surfaces 131 and 132 of the printed circuit board 130.

According to one embodiment, the lower case 210 is created by press-working a metal sheet, and the fixing member 260 is formed as a single body integrated with the lower case 210 using a drawing technique. If the second surface 132 of the printed circuit board 130 were to be used as a component mounting surface, the height of the fixing member 260 would have to be increased. But the height of the fixing member 260 that could be formed by the drawing technique is limited by the thickness of the lower case 210. In addition, if the first surface 131 of the printed circuit board 130 is used as a component mounting surface, as is shown in FIG. 7, the area shown as “B” in FIG. 7 can be used as a space for mounting the components, keeping within bounds to prevent substantial interference with the tray 220. On the contrary, if only the second surface 132 of the printed circuit board 130 were to be used as the component mounting surface, the area shown as “B” could not be used as a space for mounting components. Therefore, to most effectively utilize the space between the tray 220 and the lower case 210, it is preferable to mount electrical components including the integrated circuit element 100 on the first surface 131 of the printed circuit board 130, as is shown in FIG. 7.

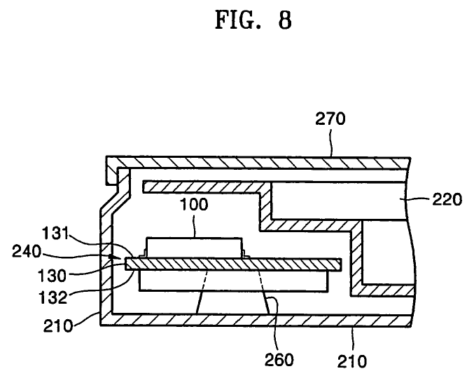

Even when electrical components including the integrated circuit element 100 are mounted on the first surface 131 of the printed circuit board 130 as is described above, it is more reasonable to use the lower case 210 than the upper case 270 as a heat absorption body to absorb the heat in the integrated circuit element 100, a greater thermal mass of the lower case 210 and to prevent interference with the tray 220. In addition, even when electrical components are mounted on both surfaces of the printed circuit board 130, as is shown in FIG. 8, there may be a case in which the integrated circuit element 100 needing to be cooled must be mounted on the first surface 131 owing to a design limitation of the printed circuit board 130. Even in this case, the lower case 210 must be used as a heat absorption body. Therefore, a device to cool an integrated circuit element, as is shown in FIGS. 3 and 4, is adapted to transfer the heat generated in the integrated circuit element 100 to the lower case 210 facing the second surface 132 of the printed circuit board 130.

Now, a device to cool an integrated circuit element 100 will be described. In the following description, reference numbers substantially like reference numbers in FIGS. 3 and 4 denote like elements, and thus their description will be omitted.

Referring to FIGS. 5 and 6, the through hole 134, which is somewhat smaller than the integrated circuit element 100, is prepared on the printed circuit board 130. When the integrated circuit element 100 is mounted on the first surface 131 of the printed circuit board 130, the first element surface 102 of the integrated circuit element 100 is exposed through the through hole 134. The cooling pad 120 is attached to the first element surface 102 of the integrated circuit element 100. A heat transfer portion 141, which makes contact with the cooling pad 120, is prepared on the lower case 210 facing the through hole 134. According to one embodiment, the heat transfer portion 141 is attached to or combined with the lower case 210 as a separate member. In this embodiment, however, the heat transfer portion 141 is formed as a single body integrated with the lower case 210. The lower case 210 is created by press-working a metal sheet, as is described above. Like the fixing member 260, the heat transfer portion 141 can be formed as a single body integrated with the lower case 210 by drawing. According to such construction, the heat generated in the integrated circuit element 100 is transferred across the cooling pad 120 and the heat transfer portion 141 to the lower case 210, so that the integrated circuit element 100 is cooled.

The above embodiment has been described by exemplifying a slim type optical disk drive, but the present invention is not limited by the above embodiment. A device to cool an integrated circuit element according to an embodiment of the present invention can be adapted to hard disk drives, such as a half-height type disk drive, which is usually installed in a desk-top computer. In addition, a device to cool an integrated circuit element according to an embodiment of the present invention can be adapted to a variety of electrical appliances, in which the heat absorption body is located on a side opposite to a component mounting surface of a printed circuit board, as well as disk drives.

With a device to cool an integrated circuit element according to an embodiment of the present invention, it is possible to remove the limitation that an integrated circuit element needing to be cooled must be mounted on the surface of a printed circuit board facing a heat absorption body, so that freedom in designing a printed circuit board is increased.

In addition, it is possible to effectively cool an integrated circuit element even when an integrated circuit element needing to be cooled is mounted on the surface of a printed circuit board opposite to a heat absorption body due to a space limitation.

Furthermore, the cost for mounting components can be reduced because components can be mounted on a single surface of a printed circuit board.

Although a few embodiments of the present invention have been shown and described, it would be appreciated by those skilled in the art that changes may be made in these embodiments without departing from the principles and spirit of the invention, the scope of which is defined in the claims and their equivalents.

1. A device to cool an integrated circuit element by transferring heat generated in the integrated circuit element to a heat absorption body, the device comprising:
a printed circuit board having a through hole, the through hole being smaller than the integrated circuit element;
a cooling pad attached to a first element surface of the integrated circuit element, the cooling pad being located inside the through hole; and
a heat transfer portion connected with the heat absorption body and making contact with the cooling pad through the through hole to transfer the heat to the heat absorption body, the integrated circuit element being mounted on a first surface of the printed circuit board and the heat absorption body being disposed facing a second surface of the printed circuit board opposite the first surface.

2. The device according to claim 1, wherein the heat transfer portion is formed as a single body integrated with the heat absorption body.

3. A disk drive comprising:
a driver unit, which comprises a spindle motor rotating a disk, and an optical pick-up unit accessing the disk to record and/or reproduce data;
a control unit, which comprises a printed circuit board having first and second surfaces, a through hole, and at least one integrated circuit element that is mounted on the first surface of the printed circuit board, the through hole being smaller than the integrated circuit element;
a heat absorption body, which is disposed facing the second surface of the printed circuit board; and
a device to cool the integrated circuit element, which connects the integrated circuit element with the heat absorption body to cool heat generated in the integrated circuit element, wherein the device for cooling the integrated circuit element comprises
a cooling pad attached to a first element surface of the integrated circuit element, the cooling pad being located inside the through hole; and
a heat transfer portion connected with the heat absorption body, and making contact with the cooling pad through the through hole to transfer the heat to the heat absorption body.

4. The disk drive according to claim 3, wherein the heat transfer portion is formed as a single body integrated with the heat absorption body.

5. The disk drive according to claim 3, wherein the printed circuit board is a single surface mounted type, in which components are mounted only on the first surface.

6. The disk drive according to claim 3, further comprising:
an upper case;
a lower case; and
a tray slidably coupled with the lower case, and on which the driving unit is mounted,
wherein the printed circuit board is coupled with the lower case, the first and second surfaces of the printed circuit board face the upper and lower cases, respectively, and the heat absorption body is the lower case.

7. The disk drive of claim 6, wherein the heat transfer portion is formed as a single body integrated with the lower case.

8. The disk drive of claim 7, wherein the lower case is made by press-working a metal sheet.

9. A device to cool an integrated element, comprising:
a printed circuit board having a through hole communicating with first and second surfaces of the printed circuit board, the integrated circuit element being mounted on the first surface such that a first element surface of the integrated circuit element is exposed through the through hole;
a cooling pad transferring heat from the integrated circuit element, connected with the first element surface;
a heat absorption body disposed facing the second surface; and
a heat transfer portion connected with the heat absorption body and contacting the cooling pad, to transfer heat from the cooling pad to the heat absorption body.

10. The device according to claim 9, wherein the integrated circuit element and the cooling pad are integrally formed.

11. The device according to claim 9, wherein the heat transfer portion and the heat absorption body are integrally formed.

12. An optical disk drive, comprising:
a lower case;
a tray slidably connected with the lower case;
a driving unit, connected with the tray, and comprising
spindle motor with a turn table, rotating an optical disk,
an optical pickup unit to record and/or reproduce data to and/or from the optical disk, and
a driving motor to move the optical pickup in a radial direction of the optical disk; and
a control unit, controlling operation of the optical disk drive, and comprising the device according to claim 9, wherein the lower case is the heat absorption body.

13. The disk drive according to claim 12, wherein the heat transfer portion and the lower case are integrally formed.
